(19) United States
(12) Patent Application Publication
(10) Pub. No.: US 2006/0121642 A1
(43) Pub. Date: Jun. 8, 2006

(54) Manufacturing process of light-emitting device

(76) Inventors: Yu-Chuan Liu, Ping-zhen City (TW); Chia-Ming Lee, Toucheng Town (TW); I-Ling Chen, Toucheng Town (TW); Jen-Inn Chyi, Pingzhen City (TW)

Correspondence Address: David I. Roche;BAKER & McKENZIE LLP, 130 E. Randolph Drive, Chicago, IL, 60601, US

(21) Appl. No.: 11/339,342

(22) Filed: Jan. 25, 2006

Related U.S. Application Data
(62) Division of application No. 10/814,872, filed on Mar. 31, 2004.

(51) Int. Cl. H01L 21/00

(52) U.S. Cl. 438/82

(57) ABSTRACT

A light-emitting device includes a multi-layer structure configured to emit a first light radiation, and a cap layer covering a surface area of the multi-layer structure while leaving exposed electrode areas defined thereon, wherein the cap layer is made of a material capable of emitting at least one second light radiation when stimulated by the first light radiation. The cap layer, being made of a material blend incorporating a passivation material and a luminescent material compound, is coated on the multi-layer structure.

This is a divisional patent application, claiming priority to U.S. patent application Ser. No. 10/814,872, filed on Mar. 31, 2004.

### FIELD OF THE INVENTION

The present invention generally relates to light-emitting devices, and particularly to the structure and manufacture of a white light-emitting device.

### DESCRIPTION OF THE RELATED ART

A white light-emitting diode device usually implements the principle of color additive mixing to produce white light. The structure of a white light-emitting device conventionally includes at least two luminescent layers. A first luminescent layer is capable of emitting a first light radiation when subjected to an electric current flow. Upon stimulation of the first light radiation, a second luminescent layer emits a second light radiation which, being combined with the first light radiation, produces white light.

FIG. 1 is a schematic view of a white light-emitting diode known in the art. The white light-emitting device 10 includes a light-emitting diode 12 attached on a zinc-selenium (ZnSe)-based substrate 14. The light-emitting diode 12 and the substrate 14 are mounted on a support frame 16. Electrodes 18 of the light-emitting diode 12 are connected via wires 20 to contact leads 22. A reflective layer 24 is placed below the ZnSe-based substrate 14 to direct light towards the viewer side. Upon the application of an electric current, the light-emitting diode 12 conventionally emits a first radiation of blue (B) light. Being stimulated by the blue light, the ZnSe-based substrate 14 in turn emits a second radiation of yellow (Y) light. The combination of blue and yellow lights results in a white light perceived by the viewer.

In operation, the prior structure of light-emitting device appears to have a service life that is unsatisfactorily limited. One reason of this limitation may be a crystalline mismatch caused by the direct attachment or formation by growth of the layers constituting the light-emitting device on the ZnSe-based substrate. Therefore, there is presently a need for the structure of a light-emitting device, particularly implemented to emit white light, which can have an improved service life and better luminous efficiency.

### SUMMARY OF THE INVENTION

The application describes a light-emitting device and a manufacturing process of the light-emitting device. In one embodiment, the light-emitting device comprises a multi-layer structure including an active layer configured to emit a first light radiation, and a cap layer covering surface areas of the multi-layer structure while leaving exposed electric connection areas defined on the multi-layer structure, wherein the cap layer includes a luminescent material compound capable of emitting at least one second light radiation when stimulated by the first light radiation.

In another embodiment, a process of forming a light-emitting device comprises forming a multi-layer structure including an active layer configured to emit a first light radiation, defining electrode areas on the multi-layer structure, and forming a cap layer covering the multi-layer structure and leaving the electrode areas externally exposed, wherein the cap layer includes a luminescent material compound capable of emitting at least one second light radiation when stimulated by the first light radiation.

The foregoing is a summary and shall not be construed to limit the scope of the claims. The operations and structures disclosed herein may be implemented in a number of ways, and such changes and modifications may be made without departing from this invention and its broader aspects. Other aspects, inventive features, and advantages of the invention, as defined solely by the claims, are described in the non-limiting detailed description set forth below.

### BRIEF DESCRIPTION OF THE DRAWINGS

FIG. 1 is a schematic view of a white light-emitting device known in the art;

FIG. 2 is a schematic view of a light-emitting device according to an embodiment of the invention;

FIG. 3A˜3D are schematic views of a process of forming a stack structure of a light-emitting device according to an embodiment of the invention;

FIG. 3E˜3F are schematic views of a process of forming a cap layer covering the stack structure of a light-emitting device according to an embodiment of the invention; and

FIG. 3G˜3J are schematic views of a process of forming a cap layer covering the stack structure of a light-emitting device according to a variant embodiment of the invention.

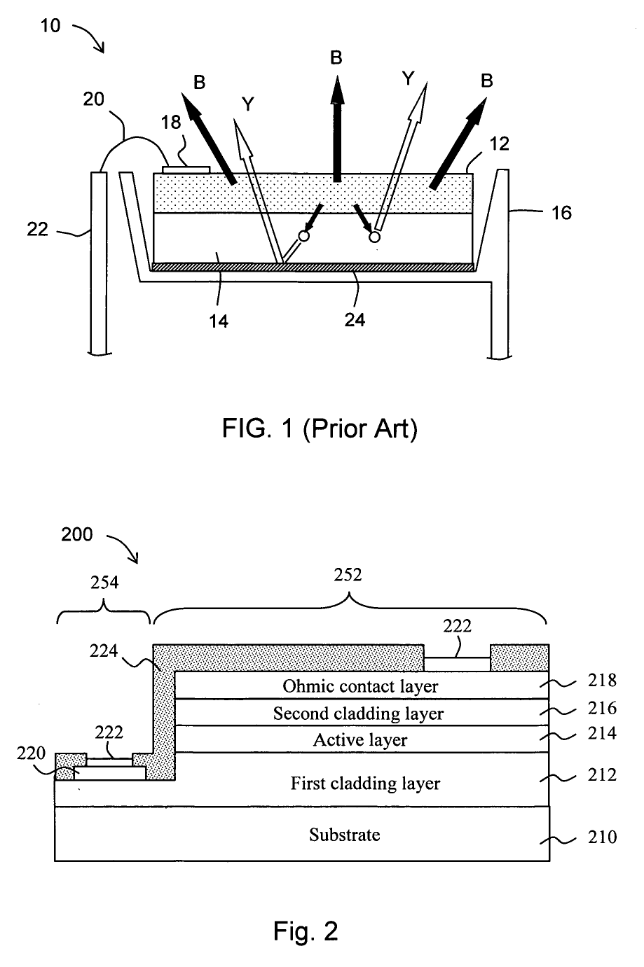

### DETAILED DESCRIPTION OF THE EMBODIMENT(S)

FIG. 2 is a schematic view of a light-emitting device according to an embodiment of the invention. In a light-emitting area 252, the light-emitting device 200 is formed from a multi-layer structure including a substrate 210, a first cladding layer 212, an active layer 214, a second cladding layer 216, and a first ohmic contact layer 218 stacked up, respectively. In an area 254 adjacent to the light-emitting area 252, the multi-layer structure is reduced to the stack of the substrate 210 and the first cladding layer 212, on which is formed a second ohmic contact layer 220. A cap layer 224 is formed to cover the areas 252, 254 and expose portions of the first and second contact layers 218, 220 where are formed connecting pads 222.

The connecting pads 222 are made of an electrically conductive material such as a metal, metallic alloys or the like, and form the electrode terminals of the light-emitting device 200. The active layer 214 is configured to emit a first light radiation upon the application of an electric current flow between the connecting pads 224. The cap layer 224 is made of a material blend including a passivation material and a luminescent material compound capable of emitting a second light radiation when being stimulated by the first light radiation. In an embodiment, the luminescent material compound can include fluorescent powders such as phosphorous-based powders or the like.

In operation, the light-emitting device 200 thereby emits first and second light radiations that combine with each other to produce a third light radiation perceived by the viewer. In an implementation of the light-emitting device for producing white light, the active layer 214 can be configured to emit a first radiation in the range of blue light, and the cap layer is configured to emit a second radiation in the range of yellow light. The combination of the blue and yellow lights produce a white light perceived externally by a viewer. The skilled artisan will appreciate that diverse wavelength ranges light can be combined to obtain white light, and the inventive features described herein are not limited to the aforementioned ranges.

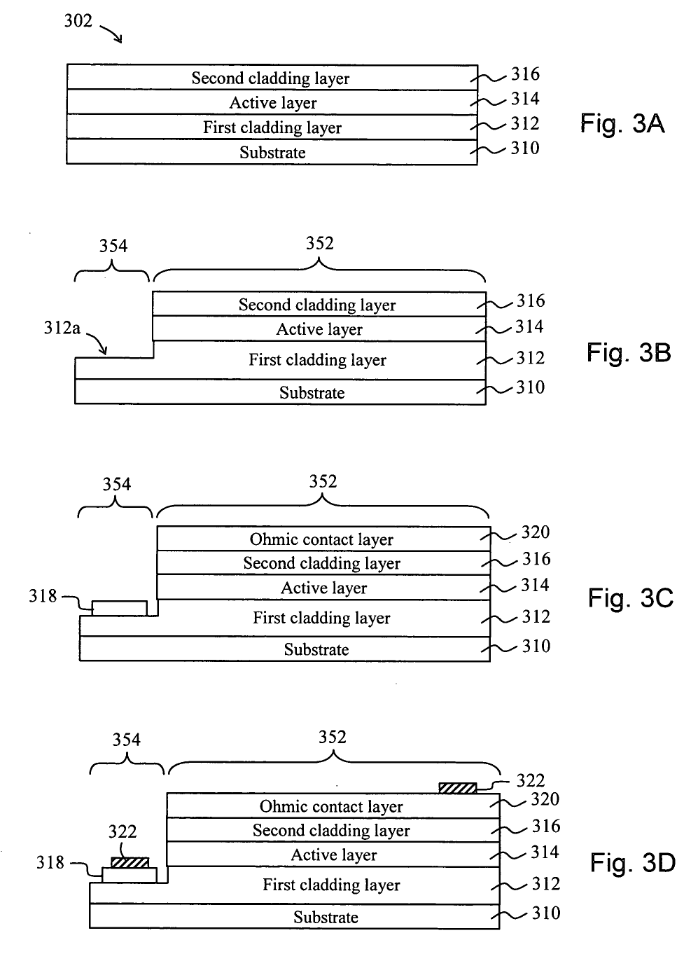

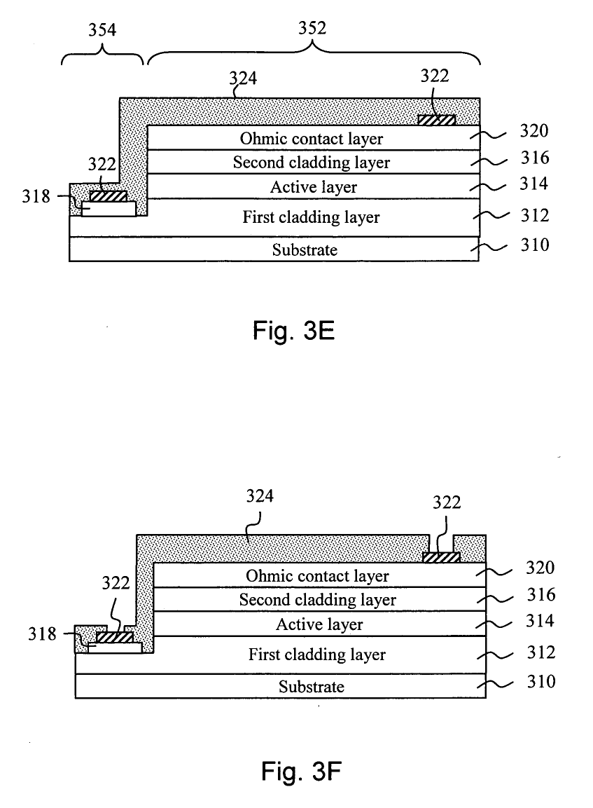

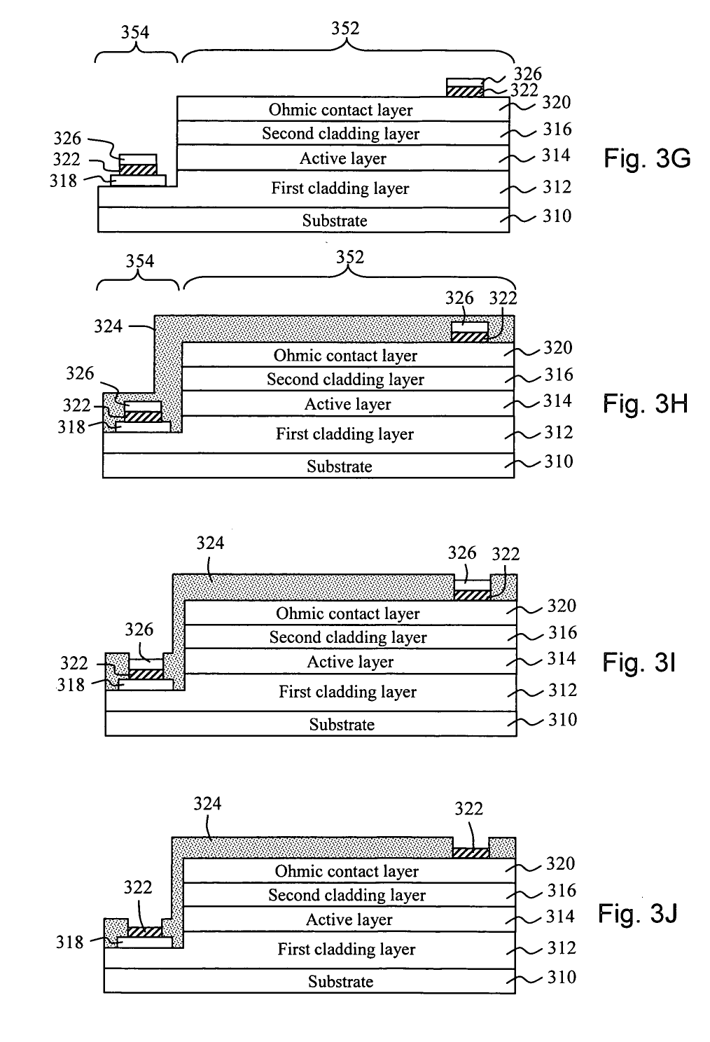

Reference now is made to FIG. 3A˜3D to describe a process of forming a stack structure of a light-emitting device according to an embodiment of the invention. FIG. 3A illustrates an intermediary stage of the manufacturing process where a multi-layer structure 302 is formed, including a substrate 310, a first cladding layer 312, an active layer 314, and a second cladding layer 316 stacked up, respectively. The substrate 310 can be made of sapphire, SiC or the like. The first cladding layer 312 can be an n-type GaN layer. The active layer 314 can include a multi-quantum well layer structure. The second cladding layer 316 can be a p-type GaN layer.

As shown in FIG. 3B, the multi-layer structure 302 is patterned to define a light emitting area 352 and an adjacent area 354 where a surface 312a of the first cladding layer 312 is exposed. According to a processing method known in the art (not shown), a photoresist pattern can be formed over the multi-layer structure 302, followed with etching through the photoresist pattern to define the areas 352, 354.

Referring to FIG. 3C, first and second ohmic contact layers 318, 320 are respectively formed on the first and second cladding layers 312, 316. The first ohmic contact layer 318 can be made of a metallic alloy such as Ti/Al, Ti/Al/Ti/Au, Ti/Al/Pt/Au, Ti/Al/Ni/Au, Ti/Al/Pd/Au, Ti/Al/Cr/Au, Ti/Al/Co/Au, Cr/Al/Cr/Au, Cr/Al/Pt/Au, Cr/Al/Pd/Au, Cr/Al/Ti/Au, Cr/Al/Co/Au, Cr/Al/Ni/Au, Pd/Al/Ti/Au, Pd/Al/Pt/Au, Pd/Al/Ni/Au, Pd/Al/Pd/Au, Pd/Al/Cr/Au, Pd/Al/Co/Au, Nd/Al/Pt/Au, Nd/Al/Ti/Au, Nd/Al/Ni/Au, Nd/Al/Cr/Au, Nd/Al/Co/A, Hf/Al/Ti/Au, Hf/Al/Pt/Au, Hf/Al/Ni/Au, Hf/Al/Pd/Au, Hf/Al/Cr/Au, Hf/Al/Co/Au, Zr/Al/Ti/Au, Zr/Al/Pt/Au, Zr/Al/Ni/Au, Zr/Al/Pd/Au, Zr/Al/Cr/Au, Zr/Al/Co/Au, TiNe/Ti/Au, TiNₓ/Pt/Au, TiNₓ/Ni/Au, TiNₓ/Pd/Au, TiNₓ/Cr/Au, TiNₓ/Co/Au TiWNₓ/Ti/Au, TiWNₓ/Pt/Au, TiWNₓ/Ni/Au, TiWNₓ/Pd/Au, TiWNₓ/Cr/Au, TiWNₓ/Co/Au, NiAl/Pt/Au, NiAl/Cr/Au, NiAl/Ni/Au, NiAl/Ti/Au, Ti/NiAl/Pt/Au, Ti/NiAl/Ti/Au, Ti/NiAl/Ni/Au, Ti/NiAl/Cr/Au or the like. The second ohmic contact layer 320 can be made of a conductive metallic alloy including Ni/Au, Ni/Pt, Ni/Pd, Ni/Co, Pd/Au, Pt/Au, Ti/Au, Cr/Au, Sn/Au, Ta/Au, TiN, TiWNₓ, WSiₓ, or the like. Alternatively, the second ohmic contact layer 320 can be made of a transparent conductive oxide such as indium tin oxide, cadmium tin oxide, ZnO:Al, ZnGa₂O₄, SnO₂:Sb, Ga₂O₃:Sn, AgInO₂:Sn, In₂O₃:Zn, NiO, MnO, FeO, Fe₂O₃, CoO, CrO, Cr₂O₃, CrO₂, CuO, SnO, Ag₂O, CuAlO₂, SrCu₂O₂, LaMnO₃, PdO or the like.

As shown in FIG. 3D, connecting pads 322 are respectively formed on the first and second ohmic contact layers 318, 320. The connecting pads 322 can be made of conductive materials such as metallic alloys. The connecting pads 322 constitute the electrodes of the light-emitting device 200 through which an electric current is applied to drive its operation.

FIG. 3E˜3I are schematic views of a process of forming the cap layer according to some embodiments of the invention. The cap layer is composed of a material blend incorporating a passivation material and a luminescent material compound capable of emitting a light radiation when stimulated by another light radiation. The passivation material can include benzocyclobutene (BCB), spin-on-glass (SOG) or the like, and the luminescent material compound can include phosphor-based fluorescent powder such as yellow phosphor-based fluorescent powder, red-green-blue phosphor-based fluorescent powder or the like.

In FIG. 3E, a liquid mixture exemplary including SOG and a phosphor-based fluorescent powder is spin-coated to cover the areas 352, 354. The liquid mixture is heated to solidify and form the cap layer 324. The cap layer 324 then is patterned to expose the connecting pads 322, as shown in FIG. 3F. Dry etching can be implemented to selectively remove portions of the cap layer 324 and expose the connecting pads 322.

FIG. 3G˜3J illustrate a process of forming a cap layer incorporating a BCB compound according to a variant embodiment of the invention. Before forming the cap layer, protective layers 326 are formed to cover the connecting pads 322, as shown in FIG. 3G. In an example, the protective layers 326 can be made of silicon dioxide, but other materials can be adequate.

Referring to FIG. 3H, a liquid mixture including BCB and a phosphor-based fluorescent powder is spin-coated to cover the areas 352, 354 of the light-emitting device. The liquid mixture is soft-baked to form a partially solidified cap layer 324.

As shown in FIG. 3I, the cap layer 324 then is selectively etched to expose the protective layers 326. Dry etching can be performed to selectively etch the cap layer 324. Subsequently, the protective layers 326 are removed via methods such as wet etching, as shown in FIG. 3J. The protective layers 326 can lift off BCB residues that may remain after the dry etching. Lastly, the cap layer 324 is baked to achieve the light-emitting device.

Realizations in accordance with the present invention have been described in the context of particular embodiments. These embodiments are meant to be illustrative and not limiting. Many variations, modifications, additions, and improvements are possible. Accordingly, plural instances may be provided for components described herein as a single instance. Boundaries between various components, operations and data stores are somewhat arbitrary, and particular operations are illustrated in the context of specific illustrative configurations. Other allocations of functionality are envisioned and may fall within the scope of claims that follow. Finally, structures and functionality presented as discrete components in the exemplary configurations may be implemented as a combined structure or component. These and other variations, modifications, additions, and improvements may fall within the scope of the invention as defined in the claims that follow.

What is claimed is:

1. A process of manufacturing a light-emitting device, comprising:
forming a multi-layer structure including an active layer configured to emit a first light radiation;
defining electrode areas on the multi-layer structure; and
forming a cap layer covering the multi-layer structure and leaving the electrode areas externally exposed, wherein the cap layer includes a luminescent material compound capable of emitting at least one second light radiation when stimulated by the first light radiation.

2. The process according to claim 1, wherein forming a cap layer comprises:
preparing a liquid mixture of a material blend including a passivation material and a luminescent material compound;
laying the liquid mixture over the multi-layer structure;
solidifying the liquid mixture to form the cap layer; and
patterning the cap layer to expose the electrode areas of the multi-layer structure.

3. The process according to claim 2, wherein laying the liquid mixture over the multi-layer structure includes spin-coating the liquid mixture over the multi-layer structure.

4. The process according to claim 2, wherein the passivation material includes benzocyclobutene, spin-on-glass or the like.

5. The process according to claim 2, wherein the luminescent material compound includes a phosphor-based powder.

6. The process according to claim 2, wherein solidifying the liquid mixture includes performing at least one baking process.

7. The process according to claim 1, further comprising forming connecting pads on the electrode areas of the multi-layer structure.

8. The process according to claim 7, wherein the connecting pads are made of a conductive metallic material.

9. The process according to claim 1, wherein forming a multi-layer structure including an active layer configured to emit a first light radiation further comprises:
forming stack of layers including a substrate, a first cladding layer, an active layer and a second cladding layer;
patterning the stack layers to expose an area of the first cladding layer; and
forming first and second ohmic contact layers on the first and second cladding layers, respectively.
